(19) United States
(12) Patent Application Publication
(10) Pub. No.: US 2008/0109698 A1
(43) Pub. Date: May 8, 2008

(54) HYBRID MIN-SUM DECODING APPARATUS WITH LOW BIT RESOLUTION FOR LDPC CODE

(75) Inventors: HAIYUN YANG, Fremont, CA (US); DINESH VENKATACHALAM, Fremont, CA (US)

Correspondence Address: FRANKLIN (LIN) YANG, 91 CANTERBURY GATE, LYNBROOK, NY, 11563, US

(73) Assignee: LEGEND SILICON, Fremont, CA (US)

(21) Appl. No.: 11/550,394

(22) Filed: Oct. 17, 2006

Related U.S. Application Data
(60) Provisional application No. 60/820,319, filed on Jul. 25, 2006.

(51) Int. Cl. H03M 13/00

(52) U.S. Cl. 714/758

(57) ABSTRACT

A new, improved method for mix min-sum decoding using a LDPC code is provided. In order to reconcile the drawbacks of the belief propagation (BP) and min-sum method, but at the same to keep the benefit of same, two major improvements have been proposed in the present invention. In the hardware implementation, due to using fixed-point implementation, it is found the better results lower error floor occurs. The second one has better performance in the range of BER=1e-3 to 1e-6. This invention proposes a method to combine the two improved methods into one, thereby achieving good performances at both cliff region and floor region.

### REFERENCE TO RELATED APPLICATIONS

This applications claims an invention which was disclosed in Provisional Application No. 60/820,319, filed Jul. 25, 2006 entitled “Receiver For An LDPC based TDS-OFDM Communication System”. The benefit under 35 USC §119(e) of the United States provisional application is hereby claimed, and the aforementioned application is hereby incorporated herein by reference.

### FIELD OF THE INVENTION

The present invention relates generally to communication devices. More specifically, the present invention relates to a hybrid min-sum decoding apparatus and method with low bit resolution decoder for a LDPC code.

### BACKGROUND

OFDM (Orthogonal frequency-division multiplexing) is known. U.S. Pat. No. 3,488,445 to Chang describes an apparatus and method for frequency multiplexing of a plurality of data signals simultaneously on a plurality of mutually orthogonal carrier waves such that overlapping, but band-limited, frequency spectra are produced without casing interchannel and intersymbol interference. Amplitude and phase characteristics of narrow-band filters are specified for each channel in terms of their symmetries alone. The same signal protection against channel noise is provided as though the signals in each channel were transmitted through an independent medium and intersymbol interference were eliminated by reducing the data rate. As the number of channels is increased, the overall data rate approaches the theoretical maximum.

OFDM transreceivers are known. U.S. Pat. No. 5,282,222 to Fattouche et al describes a method for allowing a number of wireless transceivers to exchange information (data, voice or video) with each other. A first frame of information is multiplexed over a number of wideband frequency bands at a first transceiver, and the information transmitted to a second transceiver. The information is received and processed at the second transceiver. The information is differentially encoded using phase shift keying. In addition, after a pre-selected time interval, the first transceiver may transmit again. During the preselected time interval, the second transceiver may exchange information with another transceiver in a time duplex fashion. The processing of the signal at the second transceiver may include estimating the phase differential of the transmitted signal and pre-distorting the transmitted signal. A transceiver includes an encoder for encoding information, a wideband frequency division multiplexer for multiplexing the information onto wideband frequency voice channels, and a local oscillator for upconverting the multiplexed information. The apparatus may include a processor for applying a Fourier transform to the multiplexed information to bring the information into the time domain for transmission.

Using PN (pseudo-noise) as the guard interval in an OFDM is known. U.S. Pat. No. 7,072,289 to Yang et al describes a method of estimating timing of at least one of the beginning and the end of a transmitted signal segment in the presence of time delay in a signal transmission channel. Each of a sequence of signal frames is provided with a pseudo-noise (PN) m-sequences, where the PN sequences satisfy selected orthogonality and closures relations. A convolution signal is formed between a received signal and the sequence of PN segments and is subtracted from the received signal to identify the beginning and/or end of a PN segment within the received signal. PN sequences are used for timing recovery, for carrier frequency recovery, for estimation of transmission channel characteristics, for synchronization of received signal frames, and as a replacement for guard intervals in an OFDM context.

In order to decode a low density parity check (LDPC) code, the belief propagation (BP) that demonstrates a very good performance record may be used. However, the associated BP method suitable for computer implementation is really hard if not impossible to implement in hardware. Because of the above, a simplified method suitable for computer implementation, referred a min-sum method suitable for computer implementation is typically used. Yet again the performance of the original min-sum method suitable for computer implementation is demonstrably much worse than that of the BP method suitable for computer implementation. So worse that it is typically impossible to use the min-sum method without sacrificing the required accuracy.

Therefore, in order to reconcile the drawbacks of the above two and keep the benefit of both methods, it is desirable to have an improved method and system for a hybrid min-sum decoding apparatus and method with low bit resolution decoder for a LDPC code.

### SUMMARY OF THE INVENTION

A new, improved method over belief propagation (BP) is provided.

A new, improved method for mix min-sum decoding using a LDPC code is provided.

A new, improved method using fixed-point implementation for a LDPC code is provided.

A new, improved method used in the range of BER=1e-3 to 1e-6 for a LDPC code is provided.

A new, improved method used with very low error floor (<1e-12) for a LDPC code is provided.

A new, improved method for mix min-sum decoding using a LDPC code is provided. In order to decode a low density parity check (LDPC) code, the belief propagation (BP) demonstrates a very good performance record. But the associated BP method suitable for computer implementation is hard to implement in hardware. A simplified method suitable for computer implementation, referred a min-sum method suitable for computer implementation is typically used. But the performance of the original min-sum method suitable for computer implementation is demonstrably worse than that of the BP method suitable for computer implementation. In order to reconcile the drawbacks of the two and keep the benefit of same, two major improvements have been proposed in the present invention. In the hardware implementation, due to using fixed-point implementation, it is found the better results lower error floor occurs. The second one has better performance in the range of BER=1e-3 to 1e-6. This invention propose a method to combine the two improved methods into one, thereby achieving good performance at both cliff region and floor region.

### BRIEF DESCRIPTION OF THE FIGURES

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is an example of a receiver in accordance with some embodiments of the invention.

FIG. 2 is an example of a Tanner graph based LDPC decoder with some embodiments of the invention.

FIG. 3 is a first example of a graph depicting a Performance characteristic of: 1) offset min-sum, 2) normalized min-sum, 3) hybrid min-sum, and 4) an idealized curves.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to a low density parity check (LDPC) code relating to improvement over both belief propagation (BP) method and min-sum method. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “comprises . . . a” does not, without more constraints, preclude the existence of additional identical elements in the process, method, article, or apparatus that comprises the element.

It will be appreciated that embodiments of the invention described herein may be comprised of one or more conventional processors and unique stored program instructions that control the one or more processors to implement, in conjunction with certain non-processor circuits, some, most, or all of the functions of a low density parity check (LDPC) code relating to improvement over both belief propagation (BP) method and min-sum method described herein. The non-processor circuits may include, but are not limited to, a radio receiver, a radio transmitter, signal drivers, clock circuits, power source circuits, and user input devices. As such, these functions may be interpreted as steps of a method to perform a low density parity check (LDPC) with code relating to improvement over both belief propagation (BP) method and min-sum method. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

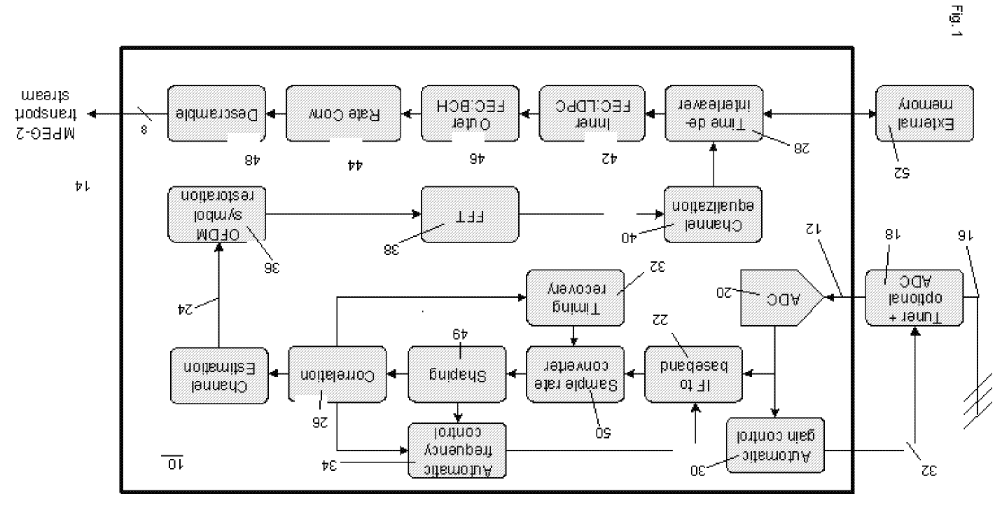

Referring to FIG. 1, a receiver 10 for implementing a LDPC based TDS-OFDM communication system is shown. In other words, FIG. 1 is a block diagram illustrating the functional blocks of an LDPC based TDS-OFDM receiver 10. Demodulation herein follows the principles of TDS-OFDM modulation scheme. Error correction mechanism is based on LDPC. The primary objectives of the receiver 10 is to determine from a noise-perturbed system, which of the finite set of waveforms have been sent by a transmitter and using an assortment of signal processing techniques reproduce the finite set of discrete messages sent by the transmitter.

The block diagram of FIG. 1 illustrates the signals and key processing steps of the receiver 10. It is assumed the input signal 12 to the receiver 10 is a down-converted digital signal. The output signal 14 of the receiver 10 is a MPEG-2 transport stream. More specifically, the RF (radio frequency) input signals 16 are received by an RF tuner 18 where the RF input signals are converted to low-IF (intermediate frequency) or zero-IF signals 12. The low-IF or zero-IF signals 12 are provided to the receiver 10 as analog signals or as digital signals (through an optional analog-to-digital converter 20).

In the receiver 10, the IF signals are converted to base-band signals 22. TDS-OFDM (Time domain synchronous-Orthogonal frequency-division multiplexing) demodulation is then performed according to the parameters of the LDPC (low-density parity-check) based TDS-OFDM modulation scheme. The output of the channel estimation 24 and correlation block 26 is sent to a time de-interleaver 28 and then to the forward error correction block. The output signal 14 of the receiver 10 is a parallel or serial MPEG-2 transport stream including valid data, synchronization and clock signals. The configuration parameters of the receiver 10 can be detected or automatically programmed, or manually set. The main configurable parameters for the receiver 10 include: (1) Sub carrier modulation type: QPSK, 16QAM, 64QAM; (2) FEC rate: 0.4, 0.6 and 0.8; (3) Guard interval: 420 or 945 symbols; (4) Time de-interleaver mode: 0, 240 or 720 symbols; (5) Control frames detection; and (6) Channel bandwidth: 6, 7, or 8 MHz.

The functional blocks of the receiver 10 are described as follows.

Automatic gain control (AGC) block 30 compares the input digitalized signal strength with a reference. The difference is filtered and the filter value 32 is used to control the gain of the amplifier 18. The analog signal provided by the tuner 12 is sampled by an ADC 20. The resulting signal is centered at a lower IF. For example, sampling a 36 MHz IF signal at 30.4 MHz results in the signal centered at 5.6 MHz. The IF to Baseband block 22 converts the lower IF signal to a complex signal in the baseband. The ADC 20 uses a fixed sampling rate. Conversion from this fixed sampling rate to the OFDM sample rate is achieved using the interpolator in block 22. The timing recovery block 32 computes the timing error and filters the error to drive a Numerically Controlled Oscillator (not shown) that controls the sample timing correction applied in the interpolator of the sample rate converter.

There can be frequency offsets in the input signal 12. The automatic frequency control block 34 calculates the offsets and adjusts the IF to baseband reference IF frequency. To improve capture range and tracking performance, frequency control is done in two stages: coarse and fine. Since the transmitted signal is square root raised cosine filtered, the received signal will be applied with the same function. It is known that signals in a TDS-OFDM system include a PN sequence preceding the IDFT symbol. By correlating the locally generated PN with the incoming signal, it is easy to find the correlation peak (so the frame start can be determined) and other synchronization information such as frequency offset and timing error. Channel time domain response is based on the signal correlation previously obtained. Frequency response is taking the FFT of the time domain response.

In TDS-OFDM, a PN sequence replaces the traditional cyclic prefix. It is thus necessary to remove the PN sequence and restore the channel spread OFDM symbol. Block 36 reconstructs the conventional OFDM symbol that can be one-tap equalized. The FFT block 38 performs a 3780 point FFT. Channel equalization 40 is carried out to the FFT 38 transformed data based on the frequency response of the channel. De-rotated data and the channel state information are sent to FEC for further processing.

In the TDS-OFDM receiver 10, the time-deinterleaver 28 is used to increase the resilience to spurious noise. The time-deinterleaver 28 is a convolutional de-interleaver which needs a memory with size B*(B−1)*M/2, where B is the number of the branch, and M is the depth. For the TDS-OFDM receiver 10 of the present embodiment, there are two modes of time-deinterleavering. For mode 1, B=52, M=240, and for mode 2, B=52, M=720.

The LDPC decoder 42 is a soft-decision iterative decoder for decoding, for example, a Quasi-Cyclic Low Density Parity Check (QC-LDPC) code provided by a transmitter (not shown). The LDPC decoder 42 is configured to decode at 3 different rates (i.e. rate 0.4, rate 0.6 and rate 0.8) of QC_LDPC codes by sharing the same piece of hardware. The iteration process is either stopped when it reaches the specified maximum iteration number (full iteration), or when the detected error is free during error detecting and correcting process (partial iteration).

The TDS-OFDM modulation/demodulation system is a multi-rate system based on multiple modulation schemes (QPSK, 16QAM, 64QAM), and multiple coding rates (0.4, 0.6, and 0.8), where QPSK stands for Quad Phase Shift Keying and QAM stands for Quadrature Amplitude Modulation. The output of BCH decoder is bit by bit. According to different modulation scheme and coding rates, the rate conversion block combines the bit output of BCH decoder to bytes, and adjusts the speed of byte output clock to make the receiver 10's MPEG packets outputs evenly distributed during the whole demodulation/decoding process.

The BCH decoder 46 is designed to decode BCH (762, 752) code, which is the shortened binary BCH code of BCH (1023, 1013). The generator polynomial is x̂10+x̂3+1.

Since the data in the transmitter has been randomized using a pseudo-random (PN) sequence before BCH encoder (not shown), the error corrected data by the LDPC/BCH decoder 46 must be de-randomized. The PN sequence is generated by the polynomial 1+x¹⁴+x¹⁵, with initial condition of 100101010000000. The de-scrambler/de-randomizer 48 will be reset to the initial condition for every signal frame. Otherwise, de-scrambler/de-randomizer 48 will be free running until reset again. The least significant 8-bit will be XORed with the input byte stream.

The data flow through the various blocks of the modulator is as follows. The received RD information 16 is processed by a digital terrestrial tuner 18 which picks the frequency bandwidth of choice to be demodulated and then downconverts the signal 16 to a baseband or low-intermediate frequency. This downconverted information 12 is then converted to the Digital domain through an analog-to-digital data converter 20.

The baseband signal after processing by a sample rate converter 50 is converted to symbols. The PN information found in the guard interval is extracted and correlated with a local PN generator to find the time domain impulse response. The FFT of the time domain impulse response gives the estimated channel response. The correlation 26 is also used for the timing recovery 32 and the frequency estimation and correction of the received signal. The OFDM symbol information in the received data is extracted and passed through a 3780 FFT 38 to obtain the symbol information back in the frequency domain. Using the estimated channel estimation previously obtained, the OFDM symbol is equalized and passed to the FEC decoder.

At the FEC decoder, the time-deinterleaver block 28 performs a deconvolution of the transmitted symbol sequence and passes the 3780 blocks to the inner LDPC decoder 42. The LDPC decoder 42 and BCH decoders 46 which run in a serial manner take in exactly 3780 symbols, remove the 36 TPS symbols and process the remaining 3744 symbols and recover the transmitted transport stream information. The rate conversion 44 adjusts the output data rate and the de-randomizer 48 reconstructs the transmitted stream information. An external memory 52 coupled to the receiver 10 provides memory thereto on a predetermined or as needed basis.

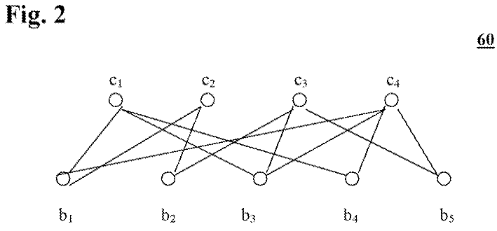

Referring to FIG. 2, a Tanner graph based LDPC decoder is shown. As can be seen, the decoding process of a low density parity check (LDPC) code can be described by a Tanner graph as shown in FIG. 2. the cⱼ are defined as check nodes, and the bᵢ are defined as bit nodes. Note the interrelationships from cⱼ to bᵢ is referred to as rⱼᵢ, and bᵢ to cⱼ as qᵢⱼ. Tanner graph is a popular way to describe LDPC decoder.

A typical, commonly used, decoding method suitable for computer implementation based on the Tanner graph is the belief propagation (BP). Before describing this method suitable for computer implementation, a few definition or denotations are defined first. They are listed in Table 1 below:

TABLE 1

| Symbols | definitions |
|---|---|
| yᵢ | received message for bit node bᵢ |
| qᵢⱼ | message to be passed from bit node bᵢ to |
| | check node cⱼ |
| rⱼᵢ | messages to be passed from check node cⱼ to |
| | bit node bᵢ |
| Rⱼ = {i:hⱼᵢ = 1} | the set of column locations of the 1's in the |
| | jth row |
| Rⱼᵢ = {i′:h_{ji′} = 1}/{i} | the set of column locations of the 1's in the |
| | jth row, excluding location i, |
| Cᵢ = {i:hⱼᵢ = 1} | the set of row locations of the 1's in the ith |
| | column |
| Cᵢⱼ = {i′:h_{ji′i} = 1}/{j} | the set of row locations of the 1's in the ith |
| | column, excluding location j. |

With the above definitions or notations, a method using the BP method suitable for computer implementation in log-domain can be expressed as

Step 1: Initialization

$$\text{indicates text missing or illegible when filed}$$

### L(qᵢⱼ) being the log-likelihood-ratio.

Step 2: Check-Node Update

$$\text{indicates text missing or illegible when filed}$$

Step 3: Bit-Node Update

$$\text{indicates text missing or illegible when filed}$$

Note that step 2 and 3 are repeated until a codeword is found or the number of iterations exceeds the limitation. Furthermore, between check-node update and bit-node update, check-node update is more complicated.

The BP method suitable for computer implementation achieves very good performance. However, the BP method suitable for computer implementation is too complicated and is not very suitable for hardware implementation since the function

$$\text{indicates text missing or illegible when filed}$$

is difficult and complicated to implement. However, it can be appreciated or approved that in this function, the smallest L(q_{i′j}) is the dominant item. Therefore, this function can be approximated as follows:

$$\text{indicates text missing or illegible when filed}$$

Therefore, the above approximation is used to replace the check node update in Step 2 is the min-sum method suitable for computer implementation. Obviously, the min-sum method suitable for computer implementation is much simpler than the BP method suitable for computer implementation. In addition, and the min-sum method is much more suitable for hardware implementation. However, the decoding performance of the min-sum can be as much as 1 dB worse than the performance of the BP method suitable for computer implementation for some LDPC codes. As such, under most circumstances, desirous results cannot be achieved. Therefore, an improved decoding method or device are desired.

Theoretically, it can be shown or approved that

$$\text{indicates text missing or illegible when filed}$$

In order to make the right-side item be closer in value to the left side item in the above inequality, min L(q_{i′j}) needs to be reduced at least somewhat in value. The min-sum can be improved in two ways. The first one, referred as normalized min-sum method suitable for computer implementation, can be expressed as

$$\text{indicates text missing or illegible when filed}$$

The second one, referred as offset min-sum method suitable for computer implementation, can be expressed as

$$\text{indicates text missing or illegible when filed}$$

Using the density function, an optimal value for α and β can be obtained, but both of them are the functions of the rate of LDPC code, the number of check-nodes, the number of bit-nodes, and the noise density of the channel. In the hardware implementation, α and β are usually fixed to a constant value α is usually a value slightly larger than 1.0, and β is usually a small value compared to most of L(qᵢⱼ).

Assume that L(q_{i′j}) is represented by n-bit. Since L(q_{i′j}) is always a positive number. If s-bit is used to express the integer part of L(q_{i′j}) and t-bit is used to express the fraction part of L(q_{i′j}), where s+t=n. Where s the whole number port and t is the fractional number portion of number n. The proposed hybrid min-sum based on both offset and normalized min-sum, can be described as

$$\text{indicates text missing or illegible when filed}$$

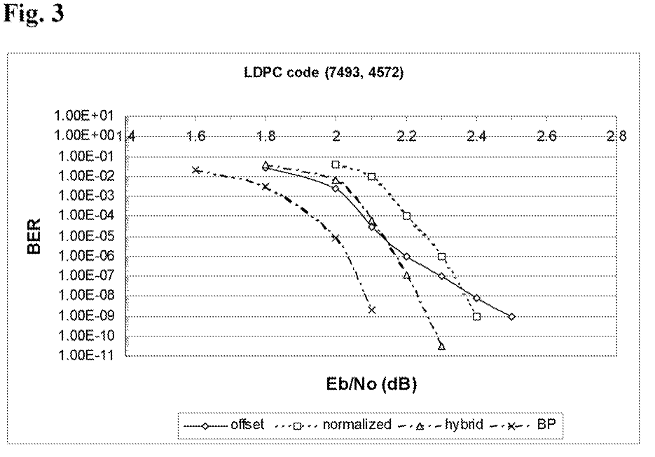

As can be seen, based upon characteristics as shown in a Tanner graph, if min L(q_{i′j})>2^{s-1}, β is used according to a optimized value of the upper equation. Otherwise, α is used according to a optimized value of the lower equation. Referring to FIG. 3, a graph depicting various curves and their effects are shown. Note that the hybrid curve is closer in shape, which traces the idealized, theatrical BP curve. For hardware implementation, the number of bits for storing L(qᵢⱼ) and L(rⱼᵢ) determine or decide directly the required memory. If as low as 5-bit is used to represent both of them, the choice of the constant value is very narrow. It is found that in a simulation, in case of low number of bits (4, 5 or 6 bits), the performance of the offset min-sum and normalized min-sum have different patterns. As shown in FIG. 2, the normalized min-sum has lower error floor, but the offset min-sum has better performance at the cliff region. Since the performances at both cliff region and error floor are important, it is better to have a solution to obtain good performance at both regions. This invention proposed a hybrid min-sum decoding method suitable for computer implementation, which combines the offset min-sum and normalized min-sum. The hybrid min-sum method suitable for computer implementation achieves good performance at both cliff region and the floor region. In other words, when the min-sum value is greater than a half of the maximum possible value, the offset min-sum is used; otherwise, the normal-based min-sum is used. Maximum possible value is decided by the number of bit for LLR. For example, if there are three bits then the maximum possible value is 7 in that 111=7 in decimal presentation.

The present invention provides two major improvements over existing methods. In the hardware implementation, due to using fixed-point implementation, it is found the better results lower error floor occurs. The second one has better performance in the range of BER=1e-3 to 1e-6. the present invention contemplates a method to combine the two improved methods into one, thereby achieving good performance at both cliff region and floor region.

The present invention contemplates a new, improved method for mix min-sum decoding using a LDPC code is provided. In order to decode a low density parity check (LDPC) code, the belief propagation (BP) demonstrates a very good performance record. But the associated BP method suitable for computer implementation is hard to implement in hardware. A simplified method suitable for computer implementation, referred a min-sum method suitable for computer implementation is typically used. But the performance of the original min-sum method suitable for computer implementation is demonstrably worse than that of the BP method suitable for computer implementation. In order to reconcile the drawbacks of the two and keep the benefit of same, two major improvements have been proposed in the present invention. In the hardware implementation, due to using fixed-point implementation, it is found the better results lower error floor occurs. The second one has better performance in the range of BER=1e-3 to 1e-6. This invention propose a method to combine the two improved methods into one, thereby achieving good performances at both cliff region and floor region.

A hybrid min-sum method for a LDPC code (low density parity check code) is provided. The method comprises the steps of: using a first computing method when a first condition is met; or using a second computing method where a second condition is met; whereby the overall quality of response approaches that of a belief propagation (BP) method that is difficult to implement in hardware.

An apparatus including an LDPC decoder, and a device suitable for implementing a hybrid min-sum method for a LDPC code (low density parity check code) is provided. The method comprises the steps of: using a first computing method when a first condition is met; or using a second computing method where a second condition is met; whereby the overall quality of response approaches that of a belief propagation (BP) method that is difficult to implement in hardware.

It is noted that the present invention contemplates using the PN sequence disclosed in U.S. Pat. No. 7,072,289 to Yang et al which is hereby incorporated herein by reference.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A hybrid min-sum method for a LDPC code (low density parity check code), the method comprising the steps of:
using a first computing method when a first condition is met; or
using a second computing method where a second condition is met;
whereby the overall quality of response approaches that of a belief propagation (BP) method that is difficult to implement in hardware.

2. The hybrid min-sum method of claim 1, wherein the first condition comprises a min-sum value is greater than a half of a maximum possible value.

3. The hybrid min-sum method of claim 1, wherein the second condition comprises a min-sum value is equal or less than a half of a maximum possible value.

4. The hybrid min-sum method of claim 1, wherein the method can be expressed as:
$$\text{indicates text missing or illegible when filed}$$

5. The hybrid min-sum method of claim 1, wherein the first computing method comprises normalized min-sum method suitable for computer implementation.

6. The hybrid min-sum method of claim 5, wherein the normalized min-sum method comprises
$$\text{indicates text missing or illegible when filed}$$

7. The hybrid min-sum method of claim 1, wherein α comprises a value slightly larger than 1.0.

8. The hybrid min-sum method of claim 1, wherein the second computing method comprises density function method suitable for computer implementation.
$$\text{indicates text missing or illegible when filed}$$

9. The hybrid min-sum method of claim 8, wherein β comprises a value that is typically smaller than the values of most L(qᵢⱼ).

10. A receiver comprising:
a LDPC decoder, and
a device suitable for implementing
a hybrid min-sum method for a LDPC code (low density parity check code), the method comprising the steps of:
using a first computing method when a first condition is met; or
using a second computing method where a second condition is met;
whereby the overall quality of response approaches that of a belief propagation (BP) method that is difficult to implement in hardware.

11. The receiver of claim 10, wherein the first condition comprises a min-sum value is greater than a half of a maximum possible value.

12. The receiver of claim 10, wherein the second condition comprises a min-sum value is equal or less than a half of a maximum possible value.

13. The receiver of claim 10, wherein the method can be expressed as:
$$\text{indicates text missing or illegible when filed}$$

14. The receiver of claim 10, wherein the first computing method comprises normalized min-sum method suitable for computer implementation.

15. The receiver of claim 14, wherein the normalized min-sum method comprises
$$\text{indicates text missing or illegible when filed}$$

16. The receiver of claim 10, wherein α comprises a value slightly larger than 1.0.

17. The receiver of claim 10, wherein the second computing method comprises density function method suitable for computer implementation.
$$\text{indicates text missing or illegible when filed}$$

18. The receiver of claim 17, wherein β comprises a value that is typically smaller than the values of most L(qᵢⱼ).
